(19) United States
(12) Patent Application Publication
(10) Pub. No.: US 2021/0202334 A1
(43) Pub. Date: Jul. 1, 2021

(54) METHODS AND APPARATUS FOR WAFER-LEVEL PACKAGING USING DIRECT WRITING

(71) Applicant: APPLIED MATERIALS, INC., Santa Clara, CA (US)

(72) Inventors: PENG SUO, SINGAPORE (SG); PRAYUDI LIANTO, SINGAPORE (SG); GUAN HUEI SEE, SINGAPORE (SG); ARVIND SUNDARRAJAN, SINGAPORE (SG); LIT PING LAM, SINGAPORE (SG); PANGYEN ONG, SINGAPORE (SG); OLIVIA KOENTJORO, Singapore (SG); WEI-SHENG LEI, SAN JOSE, CA (US); JUNGRAE PARK, CUPERTINO, CA (US)

(21) Appl. No.: 16/731,365

(22) Filed: Dec. 31, 2019

(51) Int. Cl. H01L 23/31; H01L 23/538; H01L 21/56; H01L 23/00; H01L 23/522; H01L 23/367

(52) U.S. Cl. CPC H01L 23/3114; H01L 23/5389; H01L 21/561; H01L 24/96; H01L 23/5227; H01L 23/3672; H01L 2224/04105; H01L 24/32; H01L 24/82; H01L 24/04; H01L 2924/14; H01L 2924/12042; H01L 2224/2919; H01L 24/29

(57) ABSTRACT

A method of forming a semiconductor structure on a wafer includes depositing a polymer layer on the wafer in a wafer-level packaging process, forming at least one wafer-level packaging structure in the polymer layer using a direct writing process that alters a chemical property of portions of the polymer layer that have been directly written to, and removing portions of the polymer layer that have not been written to by the direct writing process revealing the at least one wafer-level packaging structure. In some embodiments, the direct writing process is a two-photon polymerization process that uses a femtosecond laser in combination with a pair of galvanometric laser scanners to solidify portions of the polymer layer to form the wafer-level packaging structure.

### FIELD

Embodiments of the present principles generally relate to wafer-level packaging of semiconductor devices.

### BACKGROUND

Conventional types of packaging slice a wafer into individual integrated circuits (ICs) and then package the integrated circuits. Wafer-level packaging is a technology that packages integrated circuits while the integrated circuit is still part of the wafer. The technology allows for finer interconnections and, thus, smaller packages. However, the semiconductor industry has an ever-increasing demand for smaller and smaller sized packages. A typical wafer-level packaging process may utilize semi-additive process (SAP) and/or damascene process of a semiconductor structure that is often limited in resolution by photo resist (PR), photo-imageable dielectric material and/or lithography techniques. The conventional SAP and damascene process also limits the types of structures that can be formed during the wafer-level packaging processes.

Thus, the inventors have provided improved methods to form semiconductor structures during wafer-level processing.

### SUMMARY

Methods and apparatus for wafer-level packaging using a direct writing process are provided herein.

In some embodiments, a method of forming a semiconductor structure on a wafer may comprise depositing a polymer layer on the wafer in a wafer-level packaging process, forming at least one wafer-level packaging structure in the polymer layer using a direct writing process that alters a chemical property of portions of the polymer layer that have been directly written to, and removing portions of the polymer layer that have not been written to by the direct writing process revealing the at least one wafer-level packaging structure.

In some embodiments, the method may further include wherein the direct writing process is a two-photon polymerization process, wherein the two-photon polymerization process uses a femtosecond laser in combination with a pair of galvanometric laser scanners, wherein the wafer has at least one semiconductor device on a surface of the wafer before depositing the polymer layer, wherein the at least one wafer-level packaging structure is a high-aspect ratio structure with an aspect ratio of greater than approximately 5:1, wherein the high-aspect ratio structure is part of three-dimensional metal-insulator-metal capacitor, wherein the high-aspect ratio structure is a heat sink, wherein the at least one wafer-level packaging structure is at least partially hollow, wherein the at least one wafer-level packaging structure is a coil, wherein the coil is part of a three-dimensional toroidal inductor, and/or wherein the at least one wafer-level packaging structure is an interconnect.

In some embodiments, a method of forming a semiconductor structure on a wafer may comprise depositing a polymer layer on the wafer in a wafer-level packaging process, wherein the wafer has at least one semiconductor chip on a surface of the wafer, forming at least one wafer-level packaging structure in the polymer layer using a two-photon polymerization process that solidifies portions of the polymer layer, and removing portions of the polymer layer that have not been solidified by the two-photon polymerization process revealing the at least one wafer-level packaging structure.

In some embodiments, the method may further include wherein the two-photon polymerization process uses a femtosecond laser in combination with a pair of galvanometric laser scanners, wherein the at least one wafer-level packaging structure is a high-aspect ratio structure with an aspect ratio of greater than approximately 5:1, wherein the high-aspect ratio structure is part of three-dimensional metal-insulator-metal capacitor, wherein the high-aspect ratio structure is a heat sink, wherein the at least one wafer-level packaging structure is at least partially hollow, wherein the at least one wafer-level packaging structure is at least one coil of a three-dimensional toroidal inductor, and/or wherein the at least one wafer-level packaging structure is an interconnect.

In some embodiments, a non-transitory, computer readable medium may have instructions stored thereon that, when executed, cause a method for forming a semiconductor structure to be performed, the method comprising depositing a polymer layer on a wafer in a wafer-level packaging process, wherein the wafer has at least one semiconductor chip on a surface of the wafer; forming at least one wafer-level packaging structure in the polymer layer using a two-photon polymerization process that solidifies portions of the polymer layer; and removing portions of the polymer layer that have not been solidified by the two-photon polymerization process revealing the at least one wafer-level packaging structure.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of an apparatus for forming a wafer-level packaging structure in accordance with some embodiments of the present principles.

FIG. 2 depicts a cross-sectional view of a high-aspect ratio structure in accordance with some embodiments of the present principles.

FIG. 3 depicts a cross-sectional view of a hollow structure in accordance with some embodiments of the present principles.

FIG. 4 depicts a cross-sectional view of a coil structure in accordance with some embodiments of the present principles.

FIG. 5 depicts a cross-sectional view of an interconnect structure in accordance with some embodiments of the present principles.

FIG. 6 depicts an isometric view of a Z-coil interconnect structure in accordance with some embodiments of the present principles.

FIG. 7 is a method of forming a semiconductor structure in a wafer-level packaging process using a direct writing process in accordance with some embodiments of the present principles.

FIG. 8 is a method of forming a semiconductor structure in a wafer-level packaging process using a two-photon polymerization process in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods and apparatus for forming semiconductors during wafer-level packaging leverage direct writing techniques to achieve smaller scale, highly intricate, and cost effect semiconductor structures. The methods and apparatus of the present principles can provide improved capacitance density from surface-to-volume ratio for metal-insulator-metal (MIM) capacitors that are also not gated by high-k material and enable the use of mainstream materials such as, but not limited to, silicon nitride (SiN) instead of conventional tantalum pentoxide (Ta₂O₅) or hafnium dioxide (HfO₂). The methods and apparatus of the present principles can also provide greater inductance by allowing formation of an increased number of coils per volume and improved interconnections by allowing for finer detail and more complex interconnect structures.

Conventional interconnect-passive integration is limited by discrete passives on package that result in signal delays and by embedded passives (e.g., MIM and inductors) with limited configurations and/or architecture due to the requirement of SAP and/or damascene patterning. The conventional interconnect-passive integration is also limited by multi-layer damascene approaches that are costly due to multiple planarization steps and by conventional patterning techniques that use ultraviolet (UV) lithography on photo-imageable polymer which is limited in resolution by the polymer material and the lithography equipment. The methods and apparatus of the present principles directly “write” three-dimensional (3D) features and/or structures on a wafer during wafer-level packaging processes to achieve the desired interconnect and/or device functionalities. The “written” structures and/or features may include, for example, 3D MIMs, 3D toroidal inductors, and/or semiconductor interconnects. In some embodiments, the inventors have found that a two-photon polymerization process can be used to write the features and/or structures on the wafer. The two-photon polymerization process is a 3D printing technique that achieves high resolution and is capable of creating highly complex structures down to nanoscale sizing. Two-photon polymerization can be used to create structures and/or features from materials which are transmitting (i.e., the materials are not capable of being formed by linear absorption), such as polymer, through nonlinear absorption of two or more photons.

The inventors have discovered that integrating two-photon polymerization processes into wafer-level packaging processes allows for a more uniform wafer-level packaging structure formation, fewer wafer-level packaging process steps, higher complexity of wafer-level packaging structures, and lower overall cost and increased yield. The inventors have found that the two-photon polymerization concepts were not readily compatible with wafer-level packaging processes due to low yields and incompatible interfaces. The complex nature of interconnecting devices during wafer-level packaging required further advancements discovered by the inventors to allow exploitation of the two-photon polymerization process in wafer-level packaging.

In some embodiments, the inventors have found that the two-photon polymerization process can be achieved by using a femtosecond laser in combination with a pair of laser scanners (e.g., galvanometric scanners). During the two-photon polymerization process, the laser is focused on a highly confined region within a photosensitive resin which induces nonlinear absorption (i.e., two or more photons are simultaneously absorbed by the polymers) and subsequently polymerizes (solidifies) the local resin as nanoscale building blocks. Non-polymerized portions of the resin are then washed away during a development process, leaving a finished structure and/or feature remaining.

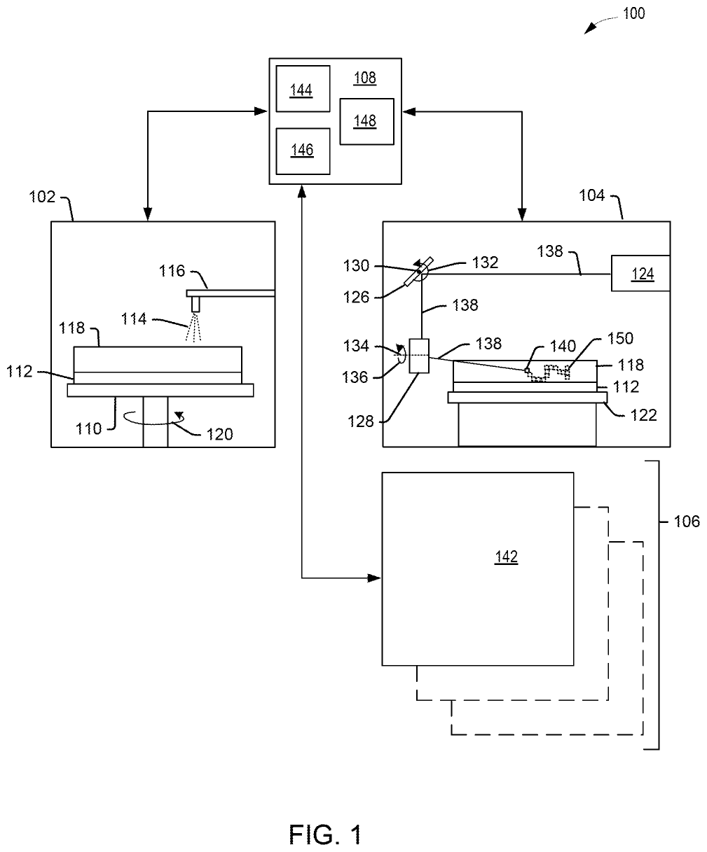

In FIG. 1, an apparatus 100 for forming a wafer-level packaging structure is illustrated in accordance with some embodiments. In some embodiments, the apparatus 100 includes a spin coating process chamber 102, a direct writing process chamber 104, additional optional process chambers 106, and a controller 108. The spin coating process chamber 102 includes a rotating pedestal 110 that supports a wafer 112. Polymer material 114 is deposited on the wafer 112 with a dispensing system 116. The rotating pedestal 110 then rotates 120 to form a uniform distribution of the polymer material 114 referred to as a polymer layer 118. During wafer-level packaging processing, the wafer 112 may have semiconductor structures/devices on a surface prior to the deposition of the polymer layer 118.

The wafer 112 with the polymer layer 118 is then transferred to the direct writing process chamber 104 and placed on a support pedestal 122. In some embodiments, the direct writing process chamber 104 may use a laser 124 and a first laser scanner 126 and a second laser scanner 128. In some embodiments, the laser 124 is a femtosecond laser and the first laser scanner 126 and the second laser scanner 128 are galvanometric scanners. In some embodiments, the first laser scanner 126 rotates 132 about an X-axis 130 and the second laser scanner 128 rotates 136 about a Y-axis 134. The combination of movement in the X-axis 130 and the Y-axis 134 allows a laser beam 138 to be focused at a specific point within the polymer layer 118. At a focal point 140, a two-photon polymerization occurs when the laser 124 is pulsed which solidifies the polymer at that location. As the focal point 140 is moved through the polymer layer 118 and the laser 124 is pulsed, a structure 150 is formed which includes the polymerized portions of the polymer layer 118. When the two-photon polymerization process is completed, the unpolymerized portions of the polymer layer 118 are removed, leaving the structure 150. In some embodiments, removal of the unpolymerized portions is accomplished by washing the wafer 112 with deionized water and/or other solutions that remove the unpolymerized portions.

In some embodiments, the structures formed on the wafer 112 may need to be conductive to function as part of the wafer-level packaging process. A plating process chamber 142 may be used to plate or coat the structure on the wafer 112 with a conductive material. After additional processing, such as plating, the wafer 112 may be transferred back to the spin coating process chamber 102 for further wafer-level packaging processing and/or an additional chamber (e.g., a dielectric deposition chamber, a metallization chamber and the like) and then transferred to the direct writing process chamber 104 to form additional structures. The controller 108 controls the operation of the apparatus 100 using a direct control or alternatively, by controlling the computers (or controllers) associated with the apparatus 100. In operation, the controller 108 enables data collection and feedback to optimize performance of the apparatus 100. The controller 108 generally includes a Central Processing Unit (CPU) 144, a memory 146, and a support circuit 148. The CPU 144 may be any form of a general-purpose computer processor that can be used in an industrial setting. The support circuit 148 is conventionally coupled to the CPU 144 and may comprise a cache, clock circuits, input/output subsystems, power supplies, and the like. Software routines, such as a method as described above may be stored in the memory 146 and, when executed by the CPU 144, transform the CPU 144 into a specific purpose computer (controller 108). The software routines may also be stored and/or executed by a second controller (not shown) that is located remotely from the apparatus 100.

The memory 146 is in the form of computer-readable storage media that contains instructions, when executed by the CPU 144, to facilitate the operation of the semiconductor processes and equipment. The instructions in the memory 146 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product define functions of the aspects. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the substrate heating system described herein, are aspects of the present principles.

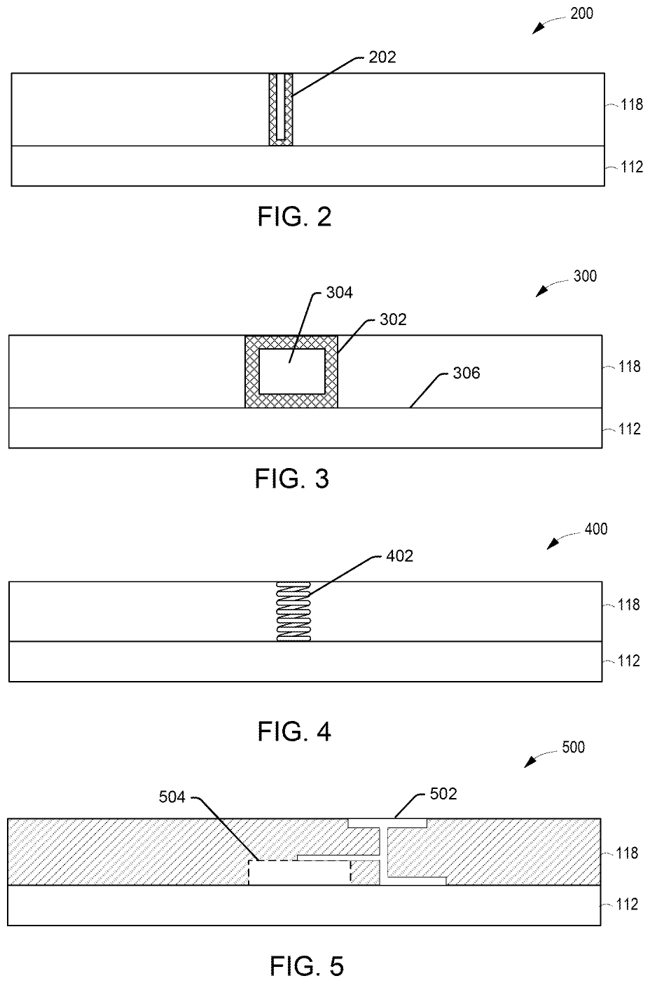

In FIG. 2, a high-aspect ratio structure 202 is shown in a cross-sectional view 200 in accordance with some embodiments. The high-aspect ratio structure 202 is formed using the direct writing process described above without the problematic issues found with conventional UV lithography and/or dry etching techniques. Conventional techniques suffer from low etching rates on the bottom as the aspect ratio increases causing malformed openings and non-uniform holes. Conventional techniques usually require thick photoresist coating and/or additional hardmask layer to realize high aspect ratio features, which increases the process complexity, cost and production cycle time. Conventional techniques may also have overhang issues at the mouth of the opening and/or necking that can occur which closes off the openings during etching. The conventional techniques also suffer from inconsistency from opening to opening, reducing overall performance in semiconductor devices such as 3D MIMs and the like. The direct writing process may be used to easily create structures with aspect ratios of approximately 5:1 to approximately 30:1 or more. In some embodiments, the high-aspect ratio structure 202 may be further capped with a dielectric and a metallization layer by chemical vapor deposition (CVD), physical vapor deposition (PVD), atomic layer deposition (ALD), and so on, to form the MIM capacitor structure. The higher aspect ratios yield increased capacitance density for wafer-level packaging which utilize 3D MIMs and the like. In some embodiments, the high-aspect ratio structure 202 may be plated or metallized by CVD, PVD, and/or electroplating techniques and serve as a heat sink to dissipate the heat generated from the integrated circuits and to ensure the device works under optimal temperature range.

In a cross-sectional view 300 of FIG. 3, a hollow or channel structure 302 is formed using the direct writing process described above. An enclosed channel structure like the channel structure 302 cannot be achieved by conventional packaging techniques. In some embodiments, deionized water and/or other liquid coolant may flow through the channel to regulate the temperature of the integrated circuits. In some embodiments, a hollow portion 304 of the channel structure 302 may be rectangular and/or circular/tube-like in shape, etc. Similarly, the channel structure 302 may have outer walls that are rectangular and/or tubular in shape and the like. In some embodiments, the channel structure 302 may intertwine/interleave with other structures formed by direct writing or other methods. In some embodiments, the channel structure 302 may be partially hollow. In some embodiments, the channel structure 302 is formed during a wafer-level packaging process with a direct writing process such that the hollow portion 304 or channel is oriented, at least partially, parallel to an upper surface plane 306 of the substrate 112.

In FIG. 4, a coil structure 402 is shown in a cross-sectional view 400 in accordance with some embodiments. The coil structure 402 is formed using the direct writing process described above. Complex structures like the coil structure 402 are not achievable with conventional UV lithography and/or etching techniques. Conventional techniques utilize SAP and/or damascene processes with masking and lithography that dramatically limit the complexity of the structures that can be formed. The direct writing process may be used to easily form complex structures such as the coil structure 402 to form 3D toroidal inductors and the like. In some embodiments, the coil structure 402 may be plated or metallized so that the coil structure 402 is conductive for use in 3D toroidal inductors.

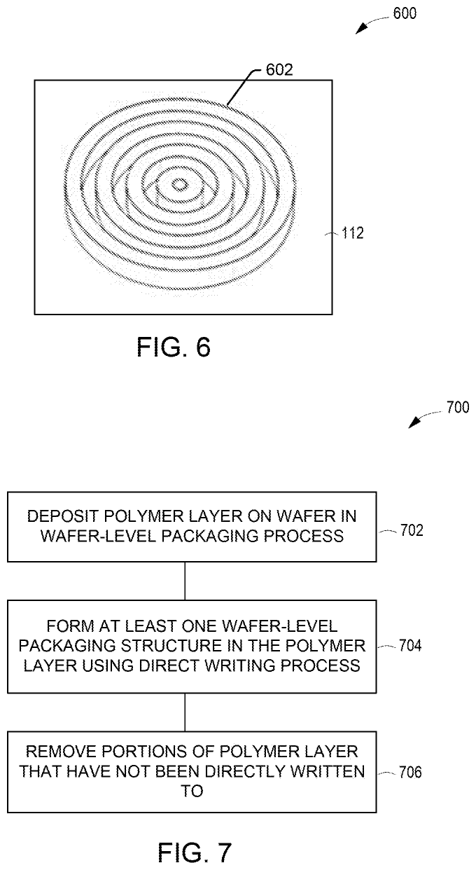

In FIG. 5, an interconnect structure 502 is shown in a cross-sectional view 500 in accordance with some embodiments. The interconnect structure 502 is formed using the direct writing process described above. Multi-level structures like the interconnect structure 502 are not achievable in one step with conventional wafer level packaging techniques. The extra processing time required by conventional techniques add to the cost and limit the types and/or shapes of structures that can be formed. The direct writing process may be used to easily form multi-level structures such as the interconnect structure 502 in a single process, saving time, cost, and materials. In some embodiments, the interconnect structure 502 may be filled with metal by electroplating technique so that the interconnect structure 502 is conductive for use in connecting devices for wafer-level packaging. In some embodiments, the interconnect structure 502 may be formed on or next to existing semiconductor devices 504 to provide wafer-level packaging connections between semiconductor devices such as chips and the like. In FIG. 6, a z-coil structure 602 is shown in an isometric view 600 in accordance with some embodiments. The z-coil structure 602 is another example of the complex interconnect structures that may be formed using the direct writing process described above.

In FIG. 7, a method 700 of forming a wafer-level packaging structure is described in accordance with some embodiments. In block 702, a polymer layer is deposited on a wafer in a wafer-level packaging process. In some embodiments, the wafer may have at least one semiconductor structure/device (e.g., semiconductor chip, redistribution layers, contacts, previously formed wafer-level packaging structures, etc.) on the wafer prior to deposition of the polymer layer. In some embodiments, a polymer material is deposited onto a wafer which is then spun to uniformly distribute the polymer material into the polymer layer. In block 704, a wafer-level packaging structure is formed in the polymer layer using a direct writing process. The direct writing process forms at least one wafer-level packaging structure in the polymer layer by altering a chemical property of portions of the polymer layer that have been directly written to. In block 706, portions of the polymer layer that have not been directly written to are removed to reveal the wafer-level packaging structure. In some embodiments, the unwritten portions may be washed away with deionized water and/or other solutions.

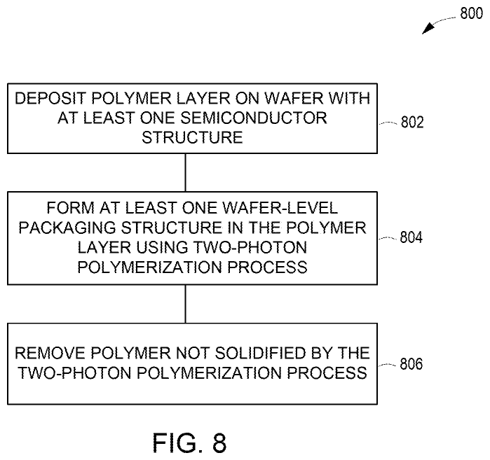

In FIG. 8, a method 800 of forming a wafer-level packaging structure is described in accordance with some embodiments. In block 802, a polymer layer is deposited on a wafer with at least one semiconductor structure in a wafer-level packaging process. In some embodiments, a polymer material is deposited onto a wafer which is then spun to uniformly distribute the polymer material into the polymer layer. In block 804, a wafer-level packaging structure is formed in the polymer layer using a two-photon polymerization process. During the two-photon polymerization process, two photons are emitted at the same time at a focal point of a laser that causes activation of a chemical reaction which polymerizes the polymer layer at the focal point when the laser is pulsed. The focal point and pulsing of the laser can be adjusted to build a polymerized 3D structure within the polymer layer. The 3D structure may be a 3D MIM capacitor, a 3D toroidal inductor, and/or 3D interconnect structure and the like. In block 806, portions of the polymer layer that have not been solidified (polymerized) by the two-photon polymerization process are removed. In some embodiments, the unpolymerized portions may be washed away with deionized water and/or other solutions.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of forming a semiconductor structure on a wafer, comprising:
depositing a polymer layer on the wafer in a wafer-level packaging process;
forming at least one wafer-level packaging structure in the polymer layer using a direct writing process that alters a chemical property of portions of the polymer layer that have been directly written to; and
removing portions of the polymer layer that have not been written to by the direct writing process revealing the at least one wafer-level packaging structure.

2. The method of claim 1, wherein the direct writing process is a two-photon polymerization process.

3. The method of claim 2, wherein the two-photon polymerization process uses a femtosecond laser in combination with a pair of galvanometric laser scanners.

4. The method of claim 1, wherein the wafer has at least one semiconductor device on a surface of the wafer before depositing the polymer layer.

5. The method of claim 1, wherein the at least one wafer-level packaging structure is a high-aspect ratio structure with an aspect ratio of greater than approximately 5:1.

6. The method of claim 5, wherein the high-aspect ratio structure is part of three-dimensional metal-insulator-metal capacitor.

7. The method of claim 5, wherein the high-aspect ratio structure is a heat sink.

8. The method of claim 1, wherein the at least one wafer-level packaging structure is at least partially hollow.

9. The method of claim 1, wherein the at least one wafer-level packaging structure is a coil.

10. The method of claim 9, wherein the coil is part of a three-dimensional toroidal inductor.

11. The method of claim 1, wherein the at least one wafer-level packaging structure is an interconnect.

12. A method of forming a semiconductor structure on a wafer, comprising:
depositing a polymer layer on the wafer in a wafer-level packaging process, wherein the wafer has at least one semiconductor chip on a surface of the wafer;
forming at least one wafer-level packaging structure in the polymer layer using a two-photon polymerization process that solidifies portions of the polymer layer; and
removing portions of the polymer layer that have not been solidified by the two-photon polymerization process revealing the at least one wafer-level packaging structure.

13. The method of claim 12, wherein the two-photon polymerization process uses a femtosecond laser in combination with a pair of galvanometric laser scanners.

14. The method of claim 12, wherein the at least one wafer-level packaging structure is a high-aspect ratio structure with an aspect ratio of greater than approximately 5:1.

15. The method of claim 14, wherein the high-aspect ratio structure is part of three-dimensional metal-insulator-metal capacitor.

16. The method of claim 14, wherein the high-aspect ratio structure is a heat sink.

17. The method of claim 12, wherein the at least one wafer-level packaging structure is at least partially hollow.

18. The method of claim 12, wherein the at least one wafer-level packaging structure is at least one coil of a three-dimensional toroidal inductor.

19. The method of claim 12, wherein the at least one wafer-level packaging structure is an interconnect.

20. A non-transitory, computer readable medium having instructions stored thereon that, when executed, cause a method for forming a semiconductor structure to be performed, the method comprising:
depositing a polymer layer on a wafer in a wafer-level packaging process, wherein the wafer has at least one semiconductor chip on a surface of the wafer;
forming at least one wafer-level packaging structure in the polymer layer using a two-photon polymerization process that solidifies portions of the polymer layer; and
removing portions of the polymer layer that have not been solidified by the two-photon polymerization process revealing the at least one wafer-level packaging structure.
